(19) United States
(12) Patent Application Publication
(10) Pub. No.: US 2025/0073841 A1
(43) Pub. Date: Mar. 6, 2025

(54) SUBSTRATE PROCESSING APPARATUS, AND ABNORMALITY DETERMINATION METHOD

(71) Applicant: EBARA CORPORATION, Tokyo (JP)

(72) Inventor: Yoshimasa OZONE, Tokyo (JP)

(21) Appl. No.: 18/815,549

(22) Filed: Aug. 26, 2024

(30) Foreign Application Priority Data
Aug. 28, 2023 (JP) 2023-137889

(51) Int. Cl. B24B 37/005; B24B 37/34; H01L 21/67; H01L 21/687

(52) U.S. Cl. CPC B24B 37/005; B24B 37/345; H01L 21/67259; H01L 21/68707

(57) ABSTRACT

Abnormality is determined with respect to delivery of a substrate to a transfer stage from a substrate holding device for a substrate polishing process. A substrate processing apparatus includes an abnormality determiner that determines abnormal delivery of the substrate to the transfer stage from the substrate holding device, based on a time difference between a first timing at which a first sensor detects that the substrate is placed on a placement surface of the transfer stage, and a second timing at which a second sensor detects that the substrate is placed on the placement surface.

### TECHNICAL FIELD

The present invention relates to a substrate processing apparatus, and an abnormality determination method.

### BACKGROUND ART

In manufacture of semiconductor devices, chemical machine polishing (CMP) apparatuses are used to flatten the surfaces of substrates. Substrates used in the manufacture of semiconductor devices are often disk-shaped. Further, the demand for flatness is increasing for not only the semiconductor devices but also for flattening the surfaces of rectangular substrates such as CCL substrates (copper clad laminate substrates), PCB (printed circuit board) substrates, photomask substrates, and display panels. Further, the demand for flattening the surfaces of the package substrates on which electronic devices are disposed such as PCB substrates is increasing.

In the substrate processing apparatus as above, a substrate holding device using an elastic film (membrane) is used to uniformize or adjust a relative pressing force between the substrate that is being polished and the polishing surface of a polishing pad. As one example, a pressure chamber formed of an elastic film (membrane) is provided in a lower portion of a top ring as the substrate holding device, and by supplying gas such as air to the pressure chamber, the substrate is pressed to the polishing surface of the polishing pad and polished.

After finishing the polishing process, the substrate holding device moves to a position above the transfer stage in the state of holding the substrate, and delivers the substrate to the transfer stage. As an example, delivery of the substrate is performed by injecting gas into a gap between the substrate and the elastic film while supplying gas to the pressure chamber, and thereby detaching the substrate from the elastic film. Seating of the substrate on the transfer stage is detected by a plurality of sensors for detecting different locations on the substrate. The substrate placed on the transfer stage is delivered to a swing transporter and is transferred to a subsequent process.

### CITATION LIST

### Patent Literature

PTL 1: Japanese Patent Laid-Open No. 2012-178608

### SUMMARY OF INVENTION

### Technical Problem

In the above-described substrate processing apparatus, damage or breakage of the substrate may be detected in the swing transporter. Because the swing transporter transfers substrates through a plurality of processing steps, if damage or breakage of a substrate is detected in the swing transporter, confirmation is performed at each of the plurality of processing steps, and the maintenance process can be complicated. Here, damage or breakage of the substrate like this may occur at the time of delivery to the transfer stage from the substrate holding device. As a result of the study of the present inventors, it has been found that especially when the elastic film of the substrate holding device is deteriorated, detachment of the substrate from the elastic film is not smoothly performed, the substrate is detached obliquely, and the substrate may be damaged or broken.

The present invention has been made in view of the above-described problem, and an object of the present invention is to propose a substrate processing apparatus and an abnormality determination method that can determine abnormality with respect to delivery of a substrate to a transfer stage from a substrate holding device for a substrate polishing process.

### Solution to Problem

According to one embodiment of the present invention, there is proposed a substrate processing apparatus for performing a polishing process on a surface to be polished of a substrate, including a polishing table for supporting a polishing pad, a substrate holding device having a substrate holding surface and a pressure chamber composed of an elastic film, and configured to hold the substrate on the substrate holding surface and press the substrate to the polishing pad by pressure in the pressure chamber, a transfer stage having a placement surface on which the substrate is placed, and configured so that the substrate is delivered to the placement surface from the substrate holding device by a detachment operation of the substrate by the substrate holding device, a plurality of sensors including a first sensor and a second sensor configured to detect different sites of the substrate to detect that the substrate is placed on the placement surface, and an abnormality determiner that determines abnormal delivery of the substrate to the transfer stage from the substrate holding device, based on a time difference between a first timing at which the first sensor detects that the substrate is placed on the placement surface, and a second timing at which the second sensor detects that the substrate is placed on the placement surface.

According to one embodiment of the present invention, there is provided an abnormality determination method that determines abnormal delivery of a substrate in a substrate processing apparatus, wherein the substrate processing apparatus includes a polishing table for supporting a polishing pad, a substrate holding device having a substrate holding surface and a pressure chamber composed of an elastic film, and configured to hold the substrate on the substrate holding surface and press the substrate to the polishing pad by pressure in the pressure chamber, and a transfer stage having a placement surface on which the substrate is placed, and configured so that the substrate is delivered to the placement surface from the substrate holding device by a detachment operation of the substrate by the substrate holing device, and the abnormality determination method includes determining abnormal delivery of the substrate to the transfer stage from the substrate holding device, based on a time difference between a first timing at which it is detected that a first site of the substrate is placed on the placement surface, and a second timing at which it is detected that a second site different from the first site of the substrate is placed on the placement surface, when it is determined that the substrate is placed on the placement surface.

### BRIEF DESCRIPTION OF DRAWINGS

FIG. 1 is a plan view showing an entire configuration of a substrate processing apparatus according to one embodiment of the present invention;

FIG. 2 is a schematic view showing a configuration of a polishing module according to the present embodiment;

FIG. 3 is a schematic sectional view of a top ring configuring a substrate holding device that holds a wafer to be polished and press the wafer to a polishing surface on a polishing table;

FIG. 4 is a schematic view showing a substrate delivery device from above;

FIG. 5A is a schematic view showing a delivery process of a wafer to the substrate delivery device from the top ring;

FIG. 5B is a schematic view showing the delivery process of the wafer to the substrate delivery device from the top ring;

FIG. 5C is a schematic view showing the delivery process of the wafer to the substrate delivery device from the top ring;

FIG. 6 is a flowchart showing an example of abnormality determination of delivery of a wafer by a controller;

FIG. 7 is a time chart showing an example of a detection signal of each of sensors in a normal state;

FIG. 8 is a time chart showing an example of a detection signal of each of the sensors in an abnormal state; and

FIG. 9 is a diagram showing an example of a time difference in seating timing of each wafer.

### DESCRIPTION OF EMBODIMENTS

Hereinafter, embodiments of a substrate processing apparatus, and an abnormality determination method according to the present invention will be described with the accompanying drawings. In the accompanying drawings, the same or similar elements are assigned with the same or similar reference sings, and redundant explanation concerning the same or similar elements may be omitted in explanation of each of the embodiments. Furthermore, features shown in each of the embodiments are also applicable to other embodiments unless they are mutually inconsistent.

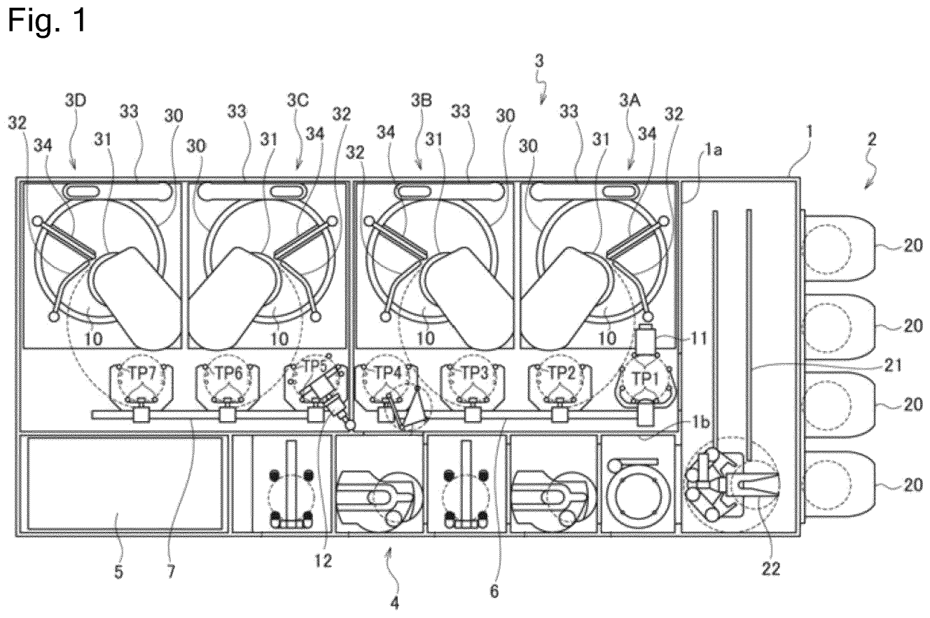

FIG. 1 is a plan view showing an entire configuration of a substrate processing apparatus according to one embodiment of the present invention. As shown in FIG. 1, the substrate processing apparatus includes a substantially rectangular housing 1, and an inside of the housing 1 is divided into a load port 2, a polishing module 3, and a cleaning module 4 by partition walls 1a and 1b. The load port 2, the polishing module 3, and the cleaning module 4 are each independently assembled and independently evacuated. In addition, the substrate processing apparatus has a controller 5 that controls a substrate processing operation.

The load port 2 includes two or more (four in the present embodiment) front loader 20 on which wafer cassettes that stock a large number of wafers (an example of substrates) are placed. These front loaders 20 are disposed adjacently to the housing 1, and arranged along a width direction (direction perpendicular to a longitudinal direction) of the substrate processing apparatus. On the front loader 20, an open cassette, a SMIF (standard manufacturing interface) pod, or a FOUP (front opening unified pod) can be mounted. Note that the present embodiment is described by using a circular semiconductor wafer as an example of the substrate, but regardless of the example like this, a square substrate may be used, for example.

Further, the load port 2 is provided with a traveling mechanism 21 extending along the arrangement of the front loaders 20. A transfer robot (loader) 22 movable along an arrangement direction of wafer cassettes is placed on the traveling mechanism 21. The transfer robot 22 can have access to the wafer cassettes mounted on the front loaders 20 by moving on the traveling mechanism 21. In the present embodiment, the transfer robot 22 includes two hands up and down. The transfer robot 22 uses an upper hand when returning a processed wafer to the wafer cassette and uses a lower hand when taking out a wafer before processing from the wafer cassette.

The load port 2 is a clean region, and an inside of the load port 2 is maintained at a higher pressure than any of an exterior of the substrate processing apparatus, the polishing module 3, and the cleaning module 4. The polishing module 3 is a dirty region because it uses slurry as a polishing liquid. Inside the polishing module 3, a negative pressure is formed, and pressure thereof is maintained to be lower than an inner pressure of the cleaning module 4.

The polishing module 3 is a region where polishing (flattening) of the wafer is performed, and includes a first polishing module 3A, a second polishing module 3B, a third polishing module 3C, and a fourth polishing module 3D. As shown in FIG. 1, in the present embodiment, the first polishing module 3A, the second polishing module 3B, the third polishing module 3C, and the fourth polishing module 3D are arranged along a longitudinal direction of the substrate processing apparatus. Note that there may be provided one, two, three, five or more polishing modules. Since the first polishing module 3A, the second polishing module 3B, the third polishing module 3C, and the fourth polishing module 3D have same configurations as one another, only the first polishing module 3A will be described hereinafter.

The first polishing module 3A includes a polishing table 30 to which a polishing pad 10 having a polishing surface is attached, and a top ring (substrate holding device) 31 for holding a wafer and polishing the wafer while pressing the wafer to the polishing pad 10 on the polishing table 30. Further, the first polishing module 3A includes a polishing liquid supply nozzle 32 for supplying a polishing liquid and a dressing liquid (for example, pure water) to the polishing pad 10, a dresser 33 for dressing the polishing surface of the polishing pad 10, and an atomizer 34 that atomizes a fluid mixture of a liquid (for example, pure water) and gas (for example, nitrogen gas) or a liquid (pure water, for example) and injects it to the polishing surface.

Next, a transfer mechanism for transferring the wafer will be described. As shown in FIG. 1, a first linear transporter 6 is disposed adjacently to the first polishing module 3A and the second polishing module 3B. The first linear transporter 6 is a mechanism that transfers wafers among four transfer positions (a first transfer position TP1, a second transfer position TP2, a third transfer position TP3, and a fourth transfer position TP4 in order from a load port side) along a direction in which the first polishing module 3A and the second polishing module 3B are arranged.

A second linear transporter 7 is disposed adjacently to the third polishing module 3C and the fourth polishing module 3D. The second linear transporter 7 is a mechanism that transfers wafers among three transfer positions (a fifth transfer position TP5, a sixth transfer position TP6, and a seventh transfer position TP7 in order from the load port side) along a direction in which the third polishing module 3C and the fourth polishing module 3D arc arranged.

A wafer is transferred to the first polishing module 3A and the second polishing module 3B by the first linear transporter 6. The top ring 31 of the first polishing module 3A moves between a polishing position and the second transfer position TP2 by a swing operation of a top ring head. Then, delivery of the wafer to the top ring 31 is performed at the second transfer position TP2. Likewise, a top ring 31 of the second polishing module 3B moves between a polishing position and the third transfer position TP3, and delivery of a wafer to the top ring 31 is performed at the third transfer position TP3. A top ring 31 of the third polishing module 3C moves between a polishing position and the sixth transfer position TP6, and delivery of a wafer to the top ring 31 is performed at the sixth transfer position TP6. A top ring 31 of the fourth polishing module 3D moves between a polishing position and the seventh transfer position TP7, and delivery of a wafer to the top ring 31 is performed at the seventh transfer position TP7.

At the first transfer position TP1, a lifter 11 for receiving a wafer from the transfer robot 22 is disposed. The wafer is delivered to the first linear transporter 6 from the transfer robot 22 via the lifter 11. A shutter (not shown) is provided at the partition wall la to be located between the lifter 11 and the transfer robot 22, and during transfer of a wafer, the shutter is opened so that the wafer is delivered to the lifter 11 from the transfer robot 22. Further, among the first linear transporter 6, the second linear transporter 7, and the cleaning module 4, a swing transporter 12 is disposed. The swing transporter 12 has a hand that is movable between the fourth transfer position TP4 and the fifth transfer position TP5, and delivery of a wafer from the first linear transporter 6 to the second linear transporter 7 is performed by the swing transporter 12. A wafer is transferred to the third polishing module 3C and/or the fourth polishing module 3D by the second linear transporter 7. Further, the wafer polished in the polishing module 3 is transferred to the cleaning module 4 via the swing transporter 12.

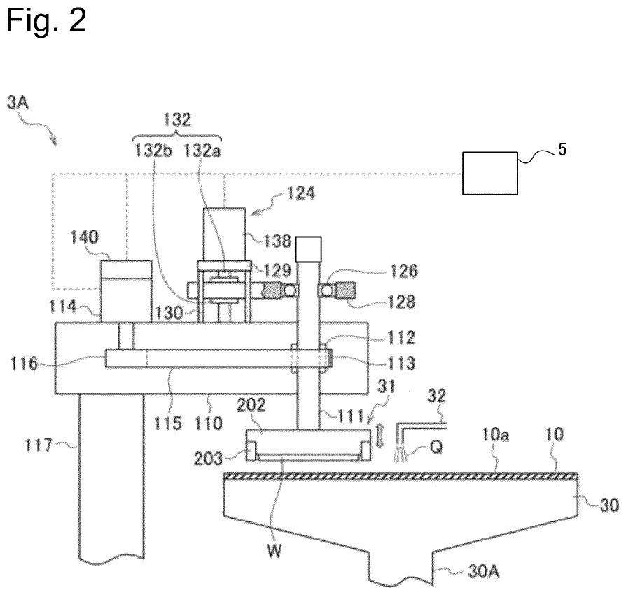

FIG. 2 is a schematic view showing a configuration of the first polishing module 3A according to the present embodiment. As shown in FIG. 2, the first polishing module 3A includes the polishing table 30, and the top ring 31 that holds a substrate such as a wafer to be polished and presses the substrate to the polishing surface on the polishing table. The polishing table 30 is connected to a motor (not shown) that is disposed below it via a table shaft 30A, and is rotatable around the table shaft 30A. The polishing pad 10 is pasted on a top surface of the polishing table 30, and a polishing surface 10a of the polishing pad 10 composes the polishing surface that polishes a wafer W. The polishing liquid supply nozzle 32 is installed above the polishing table 30, and a polishing liquid Q is supplied onto the polishing pad 10 on the polishing table 30 by the polishing liquid supply nozzle 32.

The top ring 31 includes a top ring body 202 that presses the wafer W to the polishing surface 10a, and a retainer ring 203 that holds an outer peripheral edge of the wafer W to prevent the wafer W from protruding from the top ring.

The top ring 31 is connected to a top ring shaft 111, and the top ring shaft 111 moves up and down with respect to the top ring head 110 by an up-down movement mechanism 124. By up-down movement of the top ring shaft 111, the entire top ring 31 is caused to ascend and descend to be positioned with respect to the top ring head 110.

The up-down movement mechanism 124 that moves the top ring shaft 111 and the top ring 31 up and down includes a bridge 128 that rotatably supports the top ring shaft 111 via a bearing 126, a ball screw 132 attached to the bridge 128, a support stand 129 supported by a support pillar 130, and a servo motor 138 provided on the support stand 129.

The ball screw 132 includes a screw shaft 132a connected to the servo motor 138, and a nut 132b in which the screw shaft 132a is screwed. The top ring shaft 111 moves up and down integrally with the bridge 128. Accordingly, when the servo motor 138 drives, the bridge 128 moves up and down via the ball screw 132, and thereby the top ring shaft 111 and the top ring 31 are moved up and down.

Further, the top ring shaft 111 is connected to a rotary cylinder 112 via a key (not shown). This rotary cylinder 112 includes a timing pulley 113 on an outer peripheral portion thereof. A top ring rotary motor 114 is fixed to the top ring head 110, and the above-described timing pulley 113 is connected to a timing pulley 116 provided at the top ring rotary motor 114 via a timing belt 115. Accordingly, by rotationally driving the top ring rotary motor 114, the rotary cylinder 112 and the top ring shaft 111 are integrally rotated via the timing pulley 116, the timing belt 115, and the timing pulley 113, and the top ring 31 is rotated. The top ring rotary motor 114 includes an encoder 140. The encoder 140 has a function of detecting a rotation angle position of the top ring 31 and a function of integrating the number of rotations of the top ring 31. Further, a sensor that detects a rotation angle “reference position (0 degrees)” of the top ring 31 may be additionally provided. Note that the top ring head 110 is supported by a top ring head shaft 117 rotatably supported by a frame (not shown). The top ring rotary motor 114, the servo motor 138, and the encoder 140 and other equipment within the apparatus are controlled by the controller 5.

In the first polishing module 3A configured as shown in FIG. 2, the top ring 31 can hold a substrate such as the wafer W on an undersurface thereof. The top ring head 110 is configured to be rotatable around the top ring head shaft 117, and the top ring 31 holding the wafer W on the undersurface is moved to above the polishing table 30 from the receiving position of the wafer W by rotation of the top ring head 110. Then, the top ring 31 is lowered to press the wafer W to the surface (polishing surface) 10a of the polishing pad 10. At this time, the top ring 31 and the polishing table 30 are respectively rotated, and a polishing liquid is supplied onto the polishing pad 10 from the polishing liquid supply nozzle 32 provided above the polishing table 30. In this way, the wafer W is brought into sliding contact with the polishing surface 10a and the surface of the wafer W is polished.

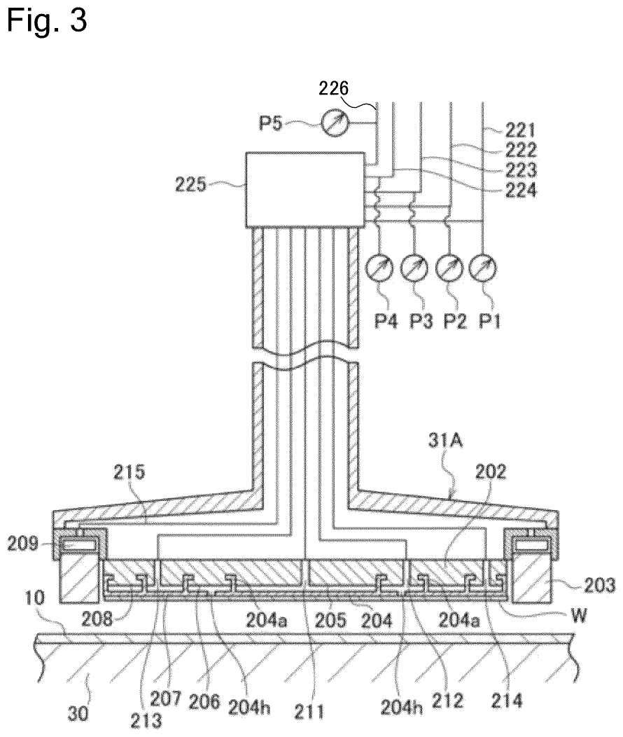

Next, the top ring (substrate holding device) 31 will be described in more detail. FIG. 3 is a schematic sectional view of the top ring 31 that composes the substrate holding device that holds the wafer W to be polished and presses the wafer W to the polishing surface on the polishing table. In FIG. 3, only main components composing the top ring 31 are shown.

As shown in FIG. 3, the top ring 31 includes the top ring body 202 that presses the wafer W to the polishing surface 10a, and the retainer ring 203 that directly presses the polishing surface 10a. The top ring body 202 is formed of a substantially disk-shaped member, and the retainer ring 203 is attached to an outer peripheral portion of the top ring body 202. The top ring body 202 is formed of a resin such as engineering plastics (for example, PEEK). A membrane (elastic film) 204 that abuts on a back surface of a wafer is attached to an undersurface of the top ring body 202. The membrane 204 defines a pressure chamber, and an undersurface thereof defines a substrate holding surface that is in contact with the wafer W. The membrane 204 is formed of a rubber material excellent in strength and durability such as ethylene propylene rubber (EPDM), polyurethane rubber, and silicon rubber.

As an example, in the example shown in FIG. 3, the membrane 204 has a plurality of concentrical partition walls 204a, and by these partition walls 204a, a circular center chamber 205, an annular ripple chamber 206, an annular outer chamber 207, and an annular edge chamber 208 are formed between a top surface of the elastic film 204 and the undersurface of the top ring body 202. That is to say, the center chamber 205 is formed in a center portion of the top ring body 202, and the ripple chamber 206, the outer chamber 207, and the edge chamber 208 are formed concentrically in order from the center to an outer periphery direction. The membrane 204 has a plurality of holes 204h that are for sucking a wafer and penetrate through the elastic film in a thickness direction of the elastic film, in a ripple area (ripple chamber 206). In the example shown in FIG. 3, the hole 204h is provided in the ripple area, but may be provided outside the ripple area. Further, in the example shown in FIG. 3, the membrane 204 has a plurality of concentrical partition walls 204a, but regardless of the example like this, the partition walls may be provided to divide a plurality of regions in a circumferential direction, or the membrane 204 may not have the partition walls 204a.

In the top ring body 202, a passage 211 communicating with the center chamber 205, a passage 212 communicating with the ripple chamber 206, a passage 213 communicating with the outer chamber 207, and a passage 214 communicating with the edge chamber 208 are respectively formed. The respective passages 211 to 214 are respectively connected to passages 221 to 224 that are connected to a vacuum source and a pressure adjuster not shown via a rotary joint 225.

Further, a retainer ring pressing chamber 209 formed of then elastic film is also formed directly above the retainer ring 203, and the retainer ring pressing chamber 209 is connected to a passage 226 via a passage 215 formed in the top ring body (carrier) 202 and the rotary joint 225. The passage 226 is connected to the vacuum source and the pressure adjuster not shown.

In the top ring 31 like this, pressure inside the center chamber 205, the ripple chamber 206, the outer chamber 207, the edge chamber 208, and the retainer ring pressing chamber 209 can be respectively adjusted independently by the vacuum source and the pressure adjuster. By the structure like this, it is possible to adjust a pressing force that presses the wafer W to the polishing pad 10 for each region of the wafer W, and adjust a pressing force with which the retainer ring 203 presses the polishing pad 10.

A series of polishing steps by the substrate processing apparatus configured as shown in FIG. 1 to FIG. 3 will be described. The top ring 31 receives the wafer W from the first linear transporter 6 and holds the wafer W by vacuum suction. The membrane 204 is provided with the plurality of holes 204h for vacuum-sucking the wafer W, and these holes 204h are connected to the vacuum source not shown. The top ring 31 holding the wafer W by vacuum suction lowers to a set position at a polishing time of the top ring which is previously set. At the set position at the polishing time, the retainer ring 203 is in contact with the surface (polishing surface) 10a of the polishing pad 10, but since the wafer W is sucked and held by the top ring 31 before polishing, there is a very small gap (for example, approximately 1 mm) between the undersurface (surface to be polished) of the wafer W and the surface of (polishing surface) of the polishing pad 10. Subsequently, the polishing table 30 and the top ring 31 are both rotationally driven. In this state, the membrane 204 on a back surface side of the wafer W is swelled, the undersurface (surface to be polished) of the wafer is brought into contact with the surface (surface to be polished) of the polishing pad 10, and by relatively moving the polishing table 30 and the top ring 31, polishing is performed until the front surface (polished surface) of the wafer W is brought into a predetermined state (for example, a predetermined film thickness).

After end of the wafer processing steps on the polishing pad 10, the wafer W is sucked by the top ring 31, the top ring 31 is raised, and moved to a substrate delivery device 800 of the first linear transporter 6, and detachment (release) of the wafer W is performed. Note that in the present embodiment, the first linear transporter 6, the second linear transporter 7, or substrate delivery devices 800 owned by them, which perform detachment of the wafer W corresponds to an example of a “transfer stage”.

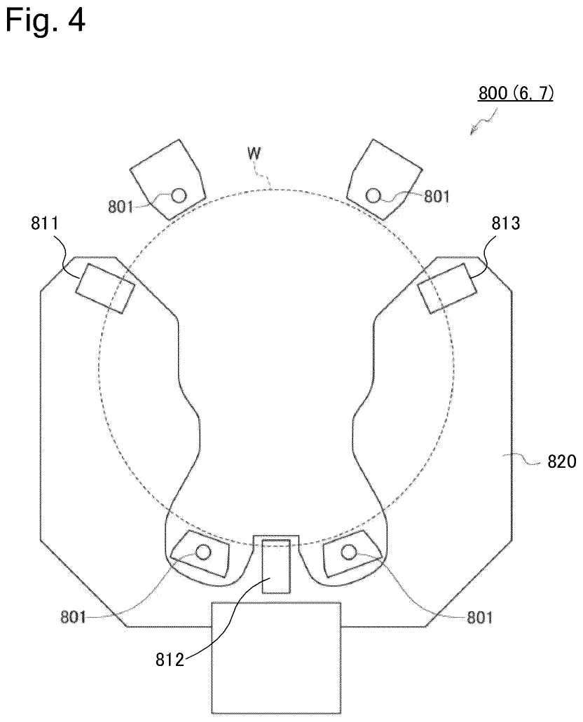

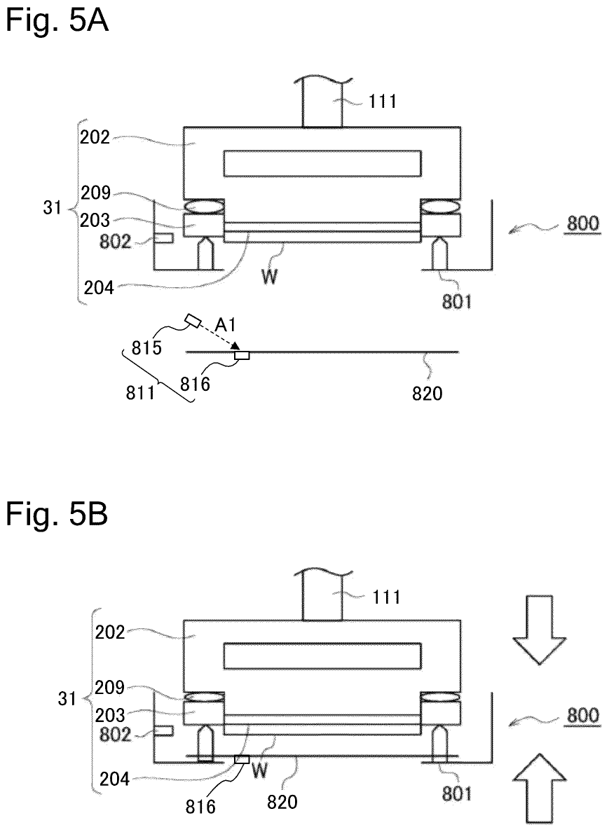

FIG. 4 is a schematic view showing the substrate delivery device 800 from above, and FIGS. 5A to 5C are schematic views showing a delivery process of the wafer W to the substrate delivery device 800 from the top ring 31. The substrate delivery device 800 includes a placement surface 820 for placing the wafer W. Further, the substrate delivery device 800 has a push-up pin 801 that pushes up the retainer ring 203 of the top ring 31. The placement surface 820 and the push-up pin 801 are configured to be able to move up and down by power sources not shown such as air cylinders respectively.

Further, the substrate delivery device 800 of the present embodiment includes three sensors 811 to 813 for detecting that the wafer W is delivered from the top ring 31 to the placement surface 820 (substrate delivery device 800). The sensors 811 to 813 are disposed to be spaced apart from one another in the circumferential direction of the wafer W so as to detect different sites of the wafer W. Detection signals by the sensors 811 to 813 are inputted to the controller 5. Note that the substrate delivery device 800 preferably has at least two sensors for detecting that the wafer W is delivered, and may have four or more sensors.

As shown in FIG. 5A, as an example, the sensor 811 includes a light emitter 815 and a light receiver 816. Note that although the sensors 812 and 813 are not shown in FIG. 5A to FIG. 5C, the sensors 812 and 813 includes similar configurations to that of the sensor 811. The light emitter 815 is, for example, a fiber sensor in which a flexible optical fiber cable is used in a light emitter of an optoelectronic sensor, and a detection head is miniaturized. The light receiver 816 is, for example, a fiber sensor in which a flexible optical fiber cable is used in a light receiver of an optoelectronic sensor, and a detection head is miniaturized.

The light emitter 815 emits light in a direction of an arrow A1 (see FIG. 5A). When the wafer W is not removed from the top ring 31, the light receiver 816 can receive light emitted from the light emitter 815. On the other hand, when the wafer W is detached from the top ring 31 and is delivered to the placement surface 820 as shown in FIG. 5C, light emitted from the light emitter 815 is shielded by the wafer W, and the light receiver 816 cannot detect the light. The controller 5 deals a time when the light cannot be detected in the light receiver 816, or a time when light intensity detected by the light receiver 816 becomes lower than a threshold value, as the time when the wafer W is detected. Note that the light source of the light emitter 815 is an LED, for example, and a color of the light may be any color (for example, red, blue, green, white, or the like).

Further, the substrate delivery device 800 of the present embodiment has, for example, three release nozzles 802 facing inward (wafer W side) (see FIG. 5A to FIG. 5C). The release nozzles 802 are connected to a pressurized fluid supply source not shown, and ejection of the pressurized fluid is controlled by the controller 5. However, the substrate delivery device 800 may have one, two, or four or more release nozzles, or may have no release nozzle.

Hereinafter, an operation of delivering the wafer W from the top ring 31 to the placement surface 820 will be described. After the end of the wafer processing steps on the polishing pad 10, the top ring 31 moves to the substrate delivery device 800 in a state where the top ring 31 sucks the wafer W (see FIG. 5A), and performs detachment (release) of the wafer W. Note that after moving to the substrate delivery device 800, a cleaning operation may be performed by rotating the top ring 31 while pure water and a chemical solution is supplied to the wafer W sucked and held by the top ring 31,

After the top ring 31 moves to the substrate delivery device 800, the top ring 31 lowers, and the placement surface 820 rises. Thereby, the placement surface 820 approaches the undersurface of the wafer W, but both of them do not contact each other. Further, by lowering of the top ring 31, the push-up pin 801 pushes up the retainer ring 203 (see FIG. 5B). In this state, the ripple chamber 206 of the membrane 204 is swelled, and vacuum suction of the wafer W is stopped to perform a wafer detachment operation. At this time, a pressurized fluid can be injected to the gap between the membrane 204 and the wafer W from the release nozzle 802. As the pressurized fluid, at least one of pressurized gas (for example, pressurized nitrogen) and a pressurized liquid (for example, pure water) can be used.

When the wafer W is placed on the placement surface 820, the wafer W is detected by the sensors 811 to 813. When all the sensors 811 to 812 detect the wafer W, the controller 5 determines that delivery of the wafer W from the top ring 31 to the placement surface 820 is completed. Thereafter, the placement surface 820 on which the wafer W is placed lowers, the top ring 31 rises, and the delivery of the wafer W is completed (see FIG. 5C).

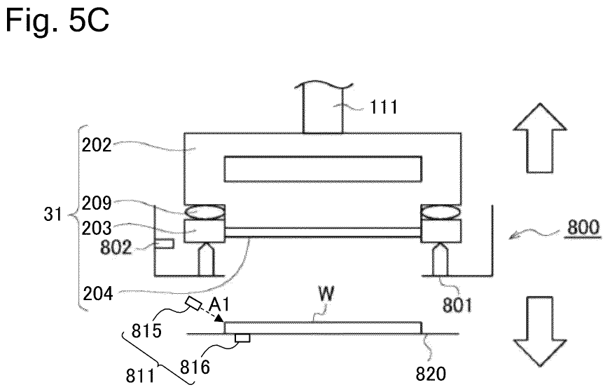

Next, determination of abnormality of delivery of the wafer W to the placement surface 820 from the top ring 31 by the controller 5 will be described. Note that in the present embodiment, the controller 5 corresponds to an example of an “abnormality determiner”. The controller 5 includes a CPU, a memory and the like, and may be configured by a microcomputer that realizes predetermined functions by using software or may be configured by a hardware circuitry that performs dedicated arithmetic processing. Note that the controller 5 is not limited to the one configured by a single device but may be configured by a plurality of devices provided to be spaced apart from one another, as an example. FIG. 6 shows an example of abnormality determination of delivery of the wafer W by the controller 5. The abnormality determination shown in FIG. 6 is executed when the polishing process of the wafer W is completed, and the wafer W is delivered to the placement surface 820 of the substrate delivery device 800 from the top ring 31.

First, the controller 5 moves the top ring 31 holding the wafer W to the substrate delivery device 800 to deliver the wafer W to the placement surface 820 from the top ring 31 (step S10). Thereby, as shown in FIG. 5A, the wafer W is disposed on the placement surface 820. The controller 5 determines whether or not a required time for a detachment operation of the wafer W elapses (step S12). Now, the detachment operation of the wafer W is not started, and it is determined that the required time has not elapsed yet (S12: No), and the flow goes to a next process (step S14). Details of the process in step S12 will be described later.

Subsequently, the controller 5 executes the detachment operation of the wafer W from the top ring 31 (step S14). This brings the top ring 31 and the substrate delivery device 800 closer to each other as shown in FIG. 5B. Further, as described above, the membrane 204 is swelled, vacuum suction of the wafer W is stopped, and a pressurized fluid is injected from the release nozzle 802.

The controller 5 determines whether or not the wafer W is detected by the sensors 811 to 813 (step S15, S16). Here, because the wafer W has rigidity and is likely to slightly jump when being detached to the placement surface 820, in order to suppress erroneous detection of the sensors 811 to 813, the controller 5 preferably determines that the wafer W is detected by the sensor 811 (812, 813) when the wafer W is continuously detected for a predetermined time (for example, one second or the like).

When the wafer W is not detected by the sensors 811 to 813 (S15, S16: No), the controller 5 returns to the process of step S12, and continues the detachment operation of the wafer W until a required time elapses (S12, S14). Here, the required time is a longer time than the time taken for the detachment operation of the wafer W in a normal state, and a time set in advance, or a time set by an external input or the like can be used. Then, when the controller 5 determines that the required time has elapsed after moving the top ring 31 to the substrate delivery device 800 (S12: Yes), it determines that the wafer W cannot be delivered to the placement surface 820 from the top ring 31 (step S22) and ends the present process. In other words, the controller 5 determines that delivery of the wafer W cannot be performed when the wafer W is not detected by the sensors 811 to 813 even after the required time elapses, although the controller 5 executes the detachment operation of the wafer W. At this time, the controller 5 can use a display device, a lamp, or a buzzer not shown to report that the wafer W cannot be delivered to the placement surface 820 from the top ring 31. Note that in place of or in addition to the process of step S12, the controller 5 may determine that the wafer W cannot be delivered to the placement surface 820 from the top ring 31 when the wafer W is not detected by the sensors 811 to 813 even after the detachment operation process of the wafer W is performed predetermined times (three times, for example) or more. In this case, the number of times of detachment operation process of the wafer W may be calculated based on the number of times of swelling the membrane 204, the number of times of ejection of the pressurized fluid from the release nozzle 802, or the like.

Further, when the wafer W is detected by one of the sensors (for example, the sensor 811) and the wafer W is not detected by the remaining sensors (for example, the sensors 812, 813) for a predetermined determination time (for example, two seconds or the like) (S15: Yes), the controller 5 may determine that the wafer W is placed on the placement surface 820 in an inclined state (step S22) and end the process. At this time, the controller 5 can use a display device, a lamp, a buzzer or the like not shown to report that the wafer W is placed on the placement surface 820 in an inclined state.

When the wafer W is detected by all the sensors 811 to 813 (S16: Yes), the controller 5 calculates a time difference Δt in seating timings detected by the respective sensors (step S18). Note that when the wafer W is detected by all the sensors 811 to 813, the controller 5 may stop light emissions from the light emitters 815 of the plurality of sensors 811 to 813. In this way, it is possible to shorten the time in which the wafer W is exposed to light by the plurality of sensors 811 to 813.

In the process of step S18, as an example, the sensor (for example, the sensor 813) that detects the wafer W first among the plurality of sensors 811 to 813 is set as a first sensor, and the sensor (for example, the sensor 811) that detects the wafer W last is set as the second sensor to calculate the time difference Δt in the seating timings. Then, the controller 5 compares the calculated time difference Δt with a predetermined abnormality determination time tref (step S20) and thereby determines whether or not the wafer W is normally delivered. Here, the abnormality determination time tref is a time (for example 0.5 seconds or the like) for determining whether or not there is a possibility that abnormality occurs to the wafer W due to the detachment operation, and a time set in advance, or a time set by an external input can be used. Note that the seating timings by the plurality of sensors 811 to 813 may be acquired by referring to times before light emissions from the light emitters 815 of the plurality of sensors 811 to 813 are stopped after the pressurized fluid is ejected from the release nozzle 802, as an example.

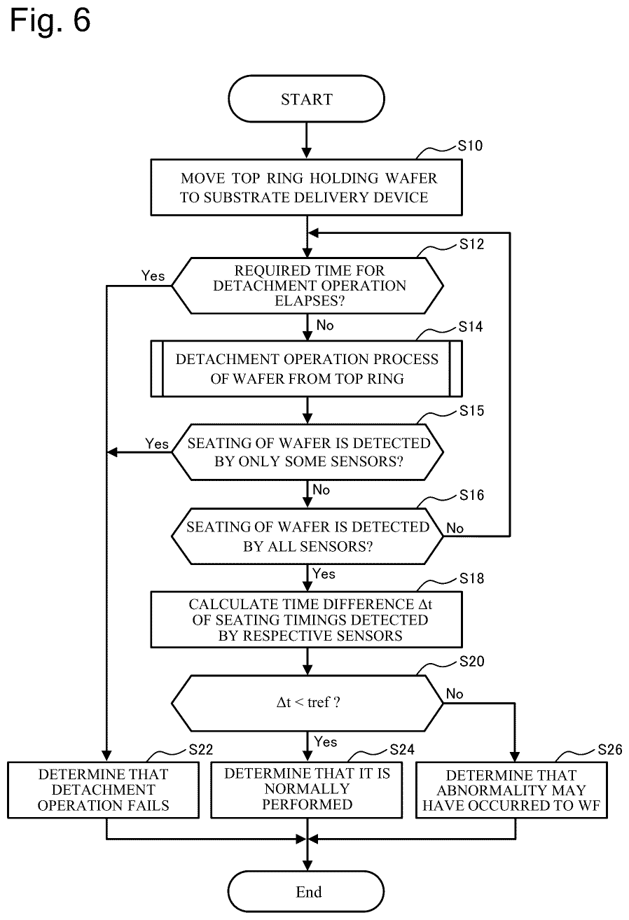

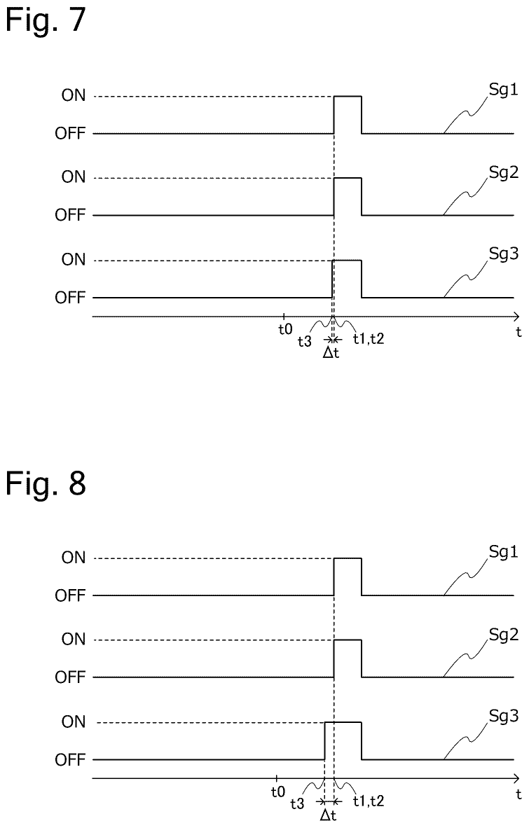

FIG. 7 is a time chart showing an example of a detection signal of each of the sensors in a normal state. In FIG. 7, detection signals Sg1 to Sg3 by the sensors 811 to 813 are shown. The detection signals Sg1 to Sg3 of the present embodiment are “OFF” when the wafer W is not detected by the sensors 811 to 813, and are “ON” when the wafer W is detected by the sensors 811 to 813. Note that in FIG. 7 and FIG. 8, when the wafer W is detected by all the sensors 811 to 813, light emissions from the light emitters 815 are stopped, and the detection signals Sg1 to Sg3 are “OFF”. As shown in the drawings, in normal delivery of the wafer W, the detection signals Sg1 to Sg3 are “ON” at substantially same timings t1 to t3 after a time t0 at which the detachment operation of the wafer W is started. Note that as described above, the controller 5 preferably determines that seating of the wafer W is detected when the wafer W continues to be detected for a predetermined time (for example, one second or the like) (when an “ON” signal continues), and acquires timings at which the detection signals Sg1 to Sg3 turn “ON” at that time as the timings (also referred to as “seating timings”) t1 to t3. Then, in the example shown in FIG. 7, the time difference Δt between the timing t3 and the timing t1 is less than the abnormality determination time tref (S20: Yes), and the controller 5 determines that the detachment operation of the wafer W is normally performed (step S24), and ends the process. When the wafer W is normally delivered, the wafer W is delivered to the swing transporter 12 from the first linear transporter 6 or the second linear transporter 7 and is transferred to the cleaning module 4.

FIG. 8 is a time chart showing an example of detection signals of the respective sensors in an abnormal state. In FIG. 8, the detection signals Sg1 to Sg3 by the sensors 811 to 813 are shown as in FIG. 7. In the example shown in FIG. 8, after the time t0 at which a detachment operation of the wafer W is started, the detection signal Sg3 turns “ON” first (timing t3), and the detection signals Sg1 and Sg2 turn “ON” a short time later (timings t1, t2). This means that the wafer W is detached from the top ring 31 in an inclined state, a site (first site) corresponding to the sensor 813 is seated on the placement surface 820 first, and sites (second sites) corresponding to the sensors 811 and 812 are thereafter seated on the placement surface 820. Then, when the time difference Δt between the timing t3 and the timing t1 is the abnormality determination time tref or more (S20: No), the controller 5 determines that there is a possibility that abnormality occurs to the wafer W by delivery of the wafer W (step S26) and ends the process.

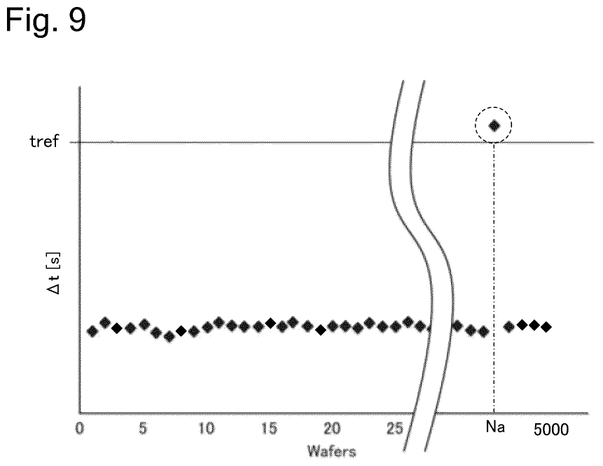

FIG. 9 is a diagram showing an example of a time difference in seating timing of each of wafers. In FIG. 9, the horizontal axis represents the number of wafers W that have been dealt after the new membrane 204 was used. The vertical axis represents the time difference Δt in the seating timing at the time of each of the wafers W being delivered from the top ring 31 to the delivery device 800. Note that the time difference Δt in seating timings is the time difference Δt between an earliest timing at which the wafer W is detected by the plurality of sensors 811 to 813 and a last timing at which the wafer W is detected. In the example shown in FIG. 9, the time difference Δt in seating timing is the abnormality determination time tref or more in an Na^{th} wafer W (see a broken line portion), and it is determined that there is a possibility that abnormality occurs to the wafer W.

Based on the study of the present inventors, it is known that even when the wafer W is detected by the plurality of sensors 811 to 813, and the delivery operation of the wafer W to the placement surface 820 from top ring 31 is completed, if the wafer W is detached with an inclination and is seated on the placement surface 820, the wafer W may be damaged or broken. Therefore, the controller 5 of the present embodiment determines whether or not the detachment operation of the wafer W from the top ring 31 is normally performed based on the time difference Δt in the seating timings of the wafer W detected by the plurality of sensors 811 to 813. Then, when the time difference Δt is the abnormality determination time tref or more, it is determined that the wafer W is detached with an inclination, and there is a possibility that an abnormality such as damage or breakage occurs to the wafer W. Thereby, it is possible to determine abnormal delivery of the wafer W, and enhance processing efficiency in the substrate processing apparatus before the wafer W is delivered to the swing transporter 12, for example.

The present invention can also be described as the following modes.

[Mode 1] According to mode 1, there is proposed a substrate processing apparatus for performing a polishing process on a surface to be polished of a substrate, and including a polishing table for supporting a polishing pad, a substrate holding device having a substrate holding surface and a pressure chamber composed of an elastic film, and configured to hold the substrate on the substrate holding surface and press the substrate to the polishing pad by pressure in the pressure chamber, a transfer stage having a placement surface on which the substrate is placed, and configured so that the substrate is delivered to the placement surface from the substrate holding device by a detachment operation of the substrate by the substrate holding device, a plurality of sensors including a first sensor and a second sensor configured to detect different sites of the substrate to detect that the substrate is placed on the placement surface, and an abnormality determiner that determines abnormal delivery of the substrate to the transfer stage from the substrate holding device, based on a time difference between a first timing at which the first sensor detects that the substrate is placed on the placement surface, and a second timing at which the second sensor detects that the substrate is placed on the placement surface. According to mode 1, it is possible to detect abnormal delivery of the substrate based on detection by the plurality of sensors for detecting that the substrate is placed on the placement surface, when the substrate is delivered to the placement surface of the transfer stage from the substrate holding device.

[Mode 2] According to mode 2, in mode 1, the plurality of sensors has at least three sensors including the first sensor and the second sensor, and the abnormality determiner determines abnormal delivery of the substrate to the transfer stage from the substrate holding device, with a sensor that detects that the substrate is placed on the placement surface first among the plurality of sensors as the first sensor, and a sensor that detects that the substrate is placed on the placement surface last among the plurality of sensors as the second sensor. According to mode 2, it is possible to determine abnormal delivery of the substrate based on detection by at least the three sensors.

[Mode 3] According to mode 3, in mode 1 or 2, the abnormality determiner determines that there is a possibility that abnormality occurs to the substrate by delivery of the substrate, when it is detected that the substrate is placed on the placement surface in all the sensors of the plurality of sensors, and the time difference is a predetermined abnormality determination time or more. According to mode 3, it is possible to determine that there is the possibility that the substrate is detached in an inclined state and abnormality occurs to the substrate.

[Mode 4] According to mode 4, in modes 1 to 3, the abnormality determiner determines that the substrate is placed in an inclined state on the placement surface, when it is detected that the substrate is placed on the placement surface in some sensors of the plurality of sensors, and it is not detected that the substrate is placed on the placement surface in remaining sensors of the plurality of sensors. According to mode 4, it is possible to determine that the substrate is placed in an inclined state on the placement surface.

[Mode 5] According to mode 5, in modes 1 to 4, the plurality of sensors each has a light emitter that emits light so that the light is blocked by the substrate when the substrate is placed on the placement surface, and a light receiver that receives the light from the light emitter, and when it is detected that the substrate is placed on the placement surface in all the sensors of the plurality of sensors, light emissions from the light emitters of the plurality of sensors are stopped.

[Mode 6] According to mode 6, in modes 1 to 5, a release nozzle configured to inject a pressurized fluid to a gap between the substrate holding surface and the substrate at a time of the detachment operation of the substrate is included. According to mode 6, it is possible to perform a detachment operation of the substrate by using injection of the pressurized fluid from the release nozzle.

[Mode 7] According to mode 7, there is proposed an abnormality determination method that determines abnormal delivery of a substrate in a substrate processing apparatus, wherein the substrate processing apparatus includes a polishing table for supporting a polishing pad, a substrate holding device having a substrate holding surface and a pressure chamber composed of an elastic film, and configured to hold the substrate on the substrate holding surface and press the substrate to the polishing pad by pressure in the pressure chamber, and a transfer stage having a placement surface on which the substrate is placed, and configured so that the substrate is delivered to the placement surface from the substrate holding device by a detachment operation of the substrate by the substrate holing device, and the abnormality determination method includes determining abnormal delivery of the substrate to the transfer stage from the substrate holding device, based on a time difference between a first timing at which it is detected that a first site of the substrate is placed on the placement surface, and a second timing at which it is detected that a second site different from the first site of the substrate is placed on the placement surface, when it is determined that the substrate is placed on the placement surface. According to mode 7, it is possible to detect abnormal delivery of the substrate based on the time difference between the timings at which it is detected that the different sites of the substrate are placed on the placement surface when the substrate is delivered to the placement surface of the transfer stage from the substrate holding device.

Although the embodiments of the present invention are described above, the above-described embodiments of the invention are to facilitate understanding of the present invention, and are not intended to limit the present invention. It goes without saying that the present invention can be changed and altered without departing from the gist of the invention, and the present invention includes the equivalents thereof. Further, within the range in which at least a part of the aforementioned problem can be solved, or in the range in which at least a part of the effect is exhibited, any combination of the embodiments and modifications is possible, and any combination or omission of the respective components described in the claims and description is possible.

The present application is based upon and claims the benefit of Japanese Patent Application No. 2023-137889 filed on Aug. 28, 2023. The entire contents of the disclosure including the description, the claims, the drawings and the abstract of Japanese Patent Application No. 2023-137889 are incorporated herein by reference. The entire disclosure including the description, the claims, the drawings and the abstract of Japanese Patent Laid-Open No. 2012-178608 (Patent Literature 1) is herein incorporated in its entirety by reference.

### REFERENCE SIGNS LIST

W wafer
2 load port
3 (3A to 3D) polishing module
4 cleaning module
5 controller
6 first linear transporter
7 second linear transporter
10 polishing pad
10a polishing surface
22 transfer robot
30 polishing table
31 top ring (substrate holding device)
32 polishing liquid supply nozzle
33 dresser
34 atomizer
202 top ring body
203 retainer ring
204 elastic film
204 membrane (elastic film)
205 center chamber
206 ripple chamber
207 outer chamber
208 edge chamber
209 retainer ring pressing chamber
800 substrate delivery device
801 push-up pin
802 release nozzle
811 to 813 sensor
815 light emitter
816 light receiver
820 placement surface

What is claimed is:

1. A substrate processing apparatus for performing a polishing process on a surface to be polished of a substrate, comprising:
a polishing table for supporting a polishing pad;
a substrate holding device having a substrate holding surface and a pressure chamber composed of an elastic film, and configured to hold the substrate on the substrate holding surface and press the substrate to the polishing pad by pressure in the pressure chamber;
a transfer stage having a placement surface on which the substrate is placed, and configured so that the substrate is delivered to the placement surface from the substrate holding device by a detachment operation of the substrate by the substrate holding device;
a plurality of sensors including a first sensor and a second sensor configured to detect different sites of the substrate to detect that the substrate is placed on the placement surface; and
an abnormality determiner that determines abnormal delivery of the substrate to the transfer stage from the substrate holding device, based on a time difference between a first timing at which the first sensor detects that the substrate is placed on the placement surface, and a second timing at which the second sensor detects that the substrate is placed on the placement surface.

2. The substrate processing apparatus according to claim 1, wherein
the plurality of sensors has at least three sensors including the first sensor and the second sensor, and
the abnormality determiner determines abnormal delivery of the substrate to the transfer stage from the substrate holding device, with a sensor that detects that the substrate is placed on the placement surface first among the plurality of sensors as the first sensor, and a sensor that detects that the substrate is placed on the placement surface last among the plurality of sensors as the second sensor.

3. The substrate processing apparatus according to claim 1, wherein the abnormality determiner determines that there is a possibility that abnormality occurs to the substrate by delivery of the substrate, when it is detected that the substrate is placed on the placement surface in all the sensors of the plurality of sensors, and the time difference is a predetermined abnormality determination time or more.

4. The substrate processing apparatus according to claim 3, wherein the abnormality determiner determines that the substrate is placed in an inclined state on the placement surface, when it is detected that the substrate is placed on the placement surface in some sensors of the plurality of sensors, and it is not detected that the substrate is placed on the placement surface in remaining sensors of the plurality of sensors.

5. The substrate processing apparatus according to claim 3, wherein the plurality of sensors each has a light emitter that emits light so that the light is blocked by the substrate when the substrate is placed on the placement surface, and a light receiver that receives the light from the light emitter, and when it is detected that the substrate is placed on the placement surface in all the sensors of the plurality of sensors, light emissions from the light emitters of the plurality of sensors are stopped.

6. The substrate processing apparatus according to claim 1, comprising a release nozzle configured to inject a pressurized fluid to a gap between the substrate holding surface and the substrate at a time of the detachment operation of the substrate.

7. An abnormality determination method that determines abnormal delivery of a substrate in a substrate processing apparatus, wherein the substrate processing apparatus comprises
a polishing table for supporting a polishing pad,
a substrate holding device having a substrate holding surface and a pressure chamber composed of an elastic film, and configured to hold the substrate on the substrate holding surface and press the substrate to the polishing pad by pressure in the pressure chamber, and
a transfer stage having a placement surface on which the substrate is placed, and configured so that the substrate is delivered to the placement surface from the substrate holding device by a detachment operation of the substrate by the substrate holing device,
the abnormality determination method, comprising determining abnormal delivery of the substrate to the transfer stage from the substrate holding device, based on a time difference between a first timing at which it is detected that a first site of the substrate is placed on the placement surface, and a second timing at which it is detected that a second site different from the first site of the substrate is placed on the placement surface, when it is determined that the substrate is placed on the placement surface.
